(19) United States
(12) Patent Application Publication
(10) Pub. No.: US 2007/0257337 A1
(43) Pub. Date: Nov. 8, 2007

(54) Shield substrate, semiconductor package, and semiconductor device

(76) Inventors: Shinichiro Yanase, Kanagawa (JP); Hajime Kai, Kanagawa (JP); Makoto Funazuka, Kanagawa (JP); Toshiaki Matsumoto, Kanagawa (JP)

Correspondence Address: MCDERMOTT WILL & EMERY LLP, 600 13TH STREET, NW, WASHINGTON, DC, 20005-3096, US

(21) Appl. No.: 11/713,098

(22) Filed: Mar. 2, 2007

(30) Foreign Application Priority Data
Mar. 2, 2006 (JP) JP 2006-056623

(51) Int. Cl. H01L 23/552

(52) U.S. Cl. 257/659; 361/818; 257/E23.114

(57) ABSTRACT

To provide a shield substrate, semiconductor package and semiconductor device which can give improved resistance to thermal stress. The shield substrate according to this invention is provided with a conductive film on which slits each having a shape through which electromagnetic wave noise does not leak are formed. These slits are rectangular slits formed in an array on the conductive film. In accordance with this configuration, the length of the straight line on the conductive film is interrupted by the slits, and thermal stress generated on the conductive film is interrupted by the slits. Thus, the thermal stress on the conductive film will not be excessively concentrated at one point, thereby preventing crack or flake-off from occurring on the conductive film.

### BACKGROUND OF THE INVENTION

1. Field of the Invention

This invention relates to a substrate or flexible substrate having a shield film capable of reducing thermal stress, and a semiconductor package and semiconductor device having the substrate.

2. Description of the Related Art

FIG. 9 illustrates a conventional semiconductor package having a wiring board equipped with a electromagnetic wave shielding layer. A semiconductor package 900 illustrated in FIG. 9 includes a semiconductor chip 901, a first wiring board 902 and a second wiring board 903.

On the semiconductor chip 901, a plurality of circuits are formed. Among them, a circuit 904 is a noise protection objective circuit. Further, in order to cut radiating noise generated from the second wiring board 903, a shield film 905 is formed on the first wiring board 902.

The first wiring board 902 having the shield film 905 is formed between the semiconductor chip 901 and the second wiring board 903. The shield film 905 of the first wiring board 902 is formed to overlie the noise protection objective circuit 904 of the semiconductor chip 901.

As shown in FIG. 9, since the shield film 905 on the first wiring board 902 is formed at the position to which the noise protection objective circuit 904 on the semiconductor chip 901 is extended in a vertical direction, the semiconductor package 900 has a configuration in which the radiating noise 906 generated from the second wiring board 903 does not propagate to the noise protection objective circuit 904 on the semiconductor chip 901.

Further, Patent Reference 1 discloses a printed wiring board in which a shield film having a shielding function is deposited on a position susceptible to external noise or a main part to be cut from the external noise, for its local shielding, in the wiring on the printed wiring board (see JP-A-6-69612).

However, when thermal stress is applied to a conductive film 905 by the semiconductor chip, the conductive film 905 serving as the shield film generates stress as indicated by thermal stress accumulating lines 2002, 2003 at a thermal stress working point 2001 on which thermal stress accumulates. Generally, although the conductive film is designed to have certain resistance, if the thermal stress is applied repeatedly, owing to thermal expansion, the conductive film 905 will crack or flake off. Thus, the conductive film 905 cannot sufficiently perform the function of the shield film so that the electromagnetic wave noise (radiating noise) may leak.

If the leaked radiating noise influences the operation of the semiconductor chip, this causes malfunction of the semiconductor device or semiconductor package.

### SUMMARY OF THE INVENTION

This invention has been accomplished in view of the above circumstance. An object of this invention is to provide a shield substrate, semiconductor package and semiconductor device which can give improved resistance to thermal stress.

The shield substrate according to this invention is provided with a conductive film on which slits each having a shape through which electromagnetic wave noise does not leak are formed.

In accordance with this configuration, the length of the straight line on the conductive film is interrupted by the slits, and thermal stress generated on the conductive film is interrupted at the slits. Thus, the thermal stress will not be excessively concentrated at one point, thereby preventing crack or flake-off from occurring on the conductive film. Accordingly, the malfunction owing to the crack or flake-off can be prevented, and resistance to thermal stress can be improved, thereby realizing the shield substrate with improved reliability.

Incidentally, since the slit shape is a shape not leaking electromagnetic wave noise, the shielding function is not impaired.

In the shield substrate according to this invention, the slits are rectangular slits and formed in an array on the conductive film. In the shield substrate according to this invention, the slits are H-like slits and formed in an array on the conductive film.

In the shield substrate according to this invention, the slits are polygonal slits and formed in an array on the conductive film.

In the shield substrate according to this invention, the slits are round slits and formed in an array on the conductive film.

In the shield substrate according to this invention, the slits are L-like slits and formed in an array on the conductive film.

In accordance with these configurations, in all the directions of the points where thermal stress accumulates, the length of the straight line on the conductive film is limited, and thermal stress is also interrupted by these slits.

Further, the semiconductor package according to this invention comprises: a first wiring board which is a source generating electromagnetic wave noise; a semiconductor chip having a noise protection objective circuit; and a second wiring board arranged between the first wiring board and the semiconductor chip and having a conductive film capable of shielding the electromagnetic wave noise, wherein slits each having a shape through which electromagnetic wave noise does not leak are formed on the conductive film.

In this configuration, the conductive film is formed so that the thermal stress propagated from the semiconductor chip is interrupted by the slits and so is not excessively concentrated, thereby preventing crack or flake-off from occurring on the conductive film. Thus, it is possible to prevent the leakage of the electromagnetic wave noise due to the crack of the conductive film from giving rise to the failure such as causing the protection objective circuit on the semiconductor chip to malfunction, thereby realizing the semiconductor package with improved reliability.

In the semiconductor package according to this invention, the slits are rectangular slits and formed in an array on the conductive film.

In the semiconductor package according to this invention, the slits are H-like slits and formed in an array on the conductive film.

In the semiconductor package according to this invention, the slits are polygonal slits and formed in an array on the conductive film.

In the semiconductor package according to this invention, the slits are round slits and formed in an array on the conductive film.

In the semiconductor package according to this invention, the slits are L-like slits and formed in an array on the conductive film.

In accordance with these configurations, in all the directions of the points where thermal stress accumulates, the length of the straight line on the conductive film is limited, and thermal stress is also interrupted by these slits.

The semiconductor device according to this invention is a semiconductor device comprising: a first wiring layer which is a source generating electromagnetic wave noise; a silicon substrate having a noise protection objective circuit; and a second wiring layer arranged between the first wiring layer and the silicon substrate and having a conductive film capable of shielding the electromagnetic wave noise from the noise protection objective circuit, wherein slits each having a shape through which electromagnetic wave noise does not leak are formed on the conductive film.

In this configuration, the conductive film is formed so that the thermal stress propagated from the circuit on the silicon substrate is interrupted by the slits and so is not excessively concentrated, thereby preventing crack or flake-off from occurring on the conductive film. Thus, it is possible to prevent the leakage of the electromagnetic wave noise due to the crack of the conductive film from giving rise to the failure such as causing the protection objective circuit on the silicon substrate to malfunction, thereby realizing the semiconductor device with improved reliability.

In the semiconductor package according to this invention, the slits are rectangular slits and formed in an array on the conductive film.

In the semiconductor device according to this invention, the slits are H-like slits and formed in an array on the conductive film.

In the semiconductor device according to this invention, the slits are polygonal slits and formed in an array on the conductive film.

In the semiconductor device according to this invention, the slits are round slits and formed in an array on the conductive film.

In the semiconductor device according to this invention, the slits are L-like slits and formed in an array on the conductive film.

In accordance with these configurations, in all the directions of the points where thermal stress accumulates, the length of the straight line on the conductive film is limited, and thermal stress is also interrupted by these slits.

In accordance with this invention, there are provided a shield substrate, semiconductor package and semiconductor device which can give improved resistance to thermal stress and improved reliability.

### BRIEF DESCRIPTION OF THE DRAWINGS

FIGS. 1A is an appearance perspective view of a shield substrate according to the first embodiment of this invention;

FIG. 1B is a plan view of a conductive film of the shield substrate seen from above according to the first embodiment of this invention;

FIG. 2 is a plan view of a conductive film of the shield substrate when seen from above according to the second embodiment of this invention;

FIG. 3 is a plan view of a conductive film of the shield substrate when seen from above according to the third embodiment of this invention;

FIG. 4 is a plan view of a conductive film of the shield substrate when seen from above according to the fourth embodiment of this invention;

FIG. 5 is a plan view of a conductive film of the shield substrate when seen from above according to the fifth embodiment of this invention;

FIG. 6 is a plan view of a conductive film of the shield substrate when seen from above according to the sixth embodiment of this invention;

FIG. 7 is a schematic arrangement view of a semiconductor package according to the seventh embodiment of this invention;

FIG. 8 is a schematic arrangement view of a semiconductor device according to the eighth embodiment of this invention;

FIG. 9 is a schematic arrangement view of a conventional semiconductor package having a wiring board equipped with an electromagnetic shield layer; and

FIG. 10 is a plan view of a conventional conductive film.

### DESCRIPTION OF THE PREFERRED EMBODIMENTS

Now referring to the drawings, a detailed explanation will be given of various embodiments of this invention.

### Embodiment 1

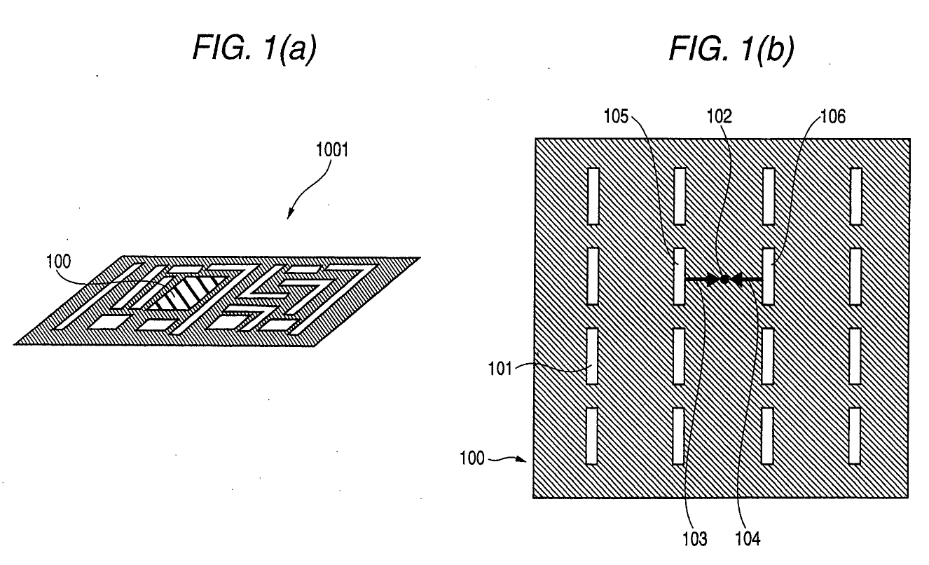

FIGS. 1A is an appearance perspective view of a shield substrate according to the first embodiment of this invention. As seen from FIG. 1A, in the vicinity of the center of a shield substrate 1001, a conductive film 100 serving as a shield film is formed.

FIG. 1B is a plan view of a conductive film of the shield substrate when seen from above according to the first embodiment of this invention. As seen from FIG. 1B, the conductive film 100 has slits 101 formed on its plane in an array.

The conductive film 100 is formed so as to have the above slits by printing/applying paste having a known shielding function on the shield substrate 1001 using the means such as printing and thereafter hardening it. The size of each of the slits is a size small enough to prevent leakage of an electromagnetic wave which is the radiating noise. So, the electromagnetic wave shielding performance of the conductive film 100 will not be attenuated.

In accordance with this configuration, for a thermal stress working point 102 where the thermal stress accumulates, a thermal stress accumulating line 103 is interrupted by a slit 105 and a thermal stress accumulating line 104 is interrupted by a slit 106. In this way, by making these slits in an array, the length of the straight line on the conductive film is limited to prevent thermal stress from being excessively concentrated, thereby preventing crack or flake-off from occurring on the conductive film. Thus, the malfunction owing to the crack or flake-off can be prevented, thereby realizing the shield substrate with improved reliability.

### Embodiment 2

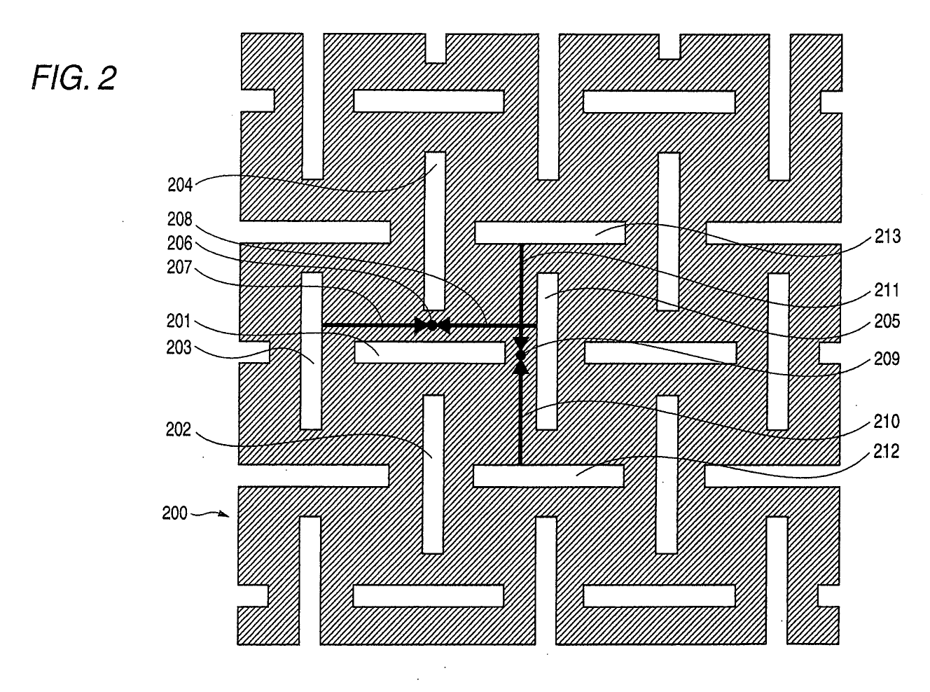

FIG. 2 is a plan view of a conductive film of the shield substrate when seen from above according to the second embodiment of this invention. In the following description, like reference symbols refer to like constituent elements in the above description, and the description thereof is omitted. The feature of this embodiment resides in that rectangular slits are formed vertically and horizontally in an array on a conductive film.

In order to make these slits, first, a rectangular slit 201 is formed on a conductive film 200. Next, rectangular slits 202, 203, 204, 205 formed by rotating the rectangular slit 201 by 90 degrees are arranged adjacently to one another. Next, all the rectangular slits are arranged vertically and horizontally in an array to provide a configuration of the rectangular slits 201, 202, 203, 204, 205.

In accordance with this configuration, for a thermal stress working point 206, a thermal stress accumulating line 207 is interrupted by the rectangular slit 203 and a thermal stress accumulating line 208 is interrupted by the rectangular slit 205. Further, for a thermal stress working point 209, a thermal stress accumulating line 210 is interrupted by the rectangular slit 212 and a thermal stress accumulating line 211 is interrupted by the rectangular slit 213. In this way, in all the directions of the points where thermal stress accumulates, the length of the straight line on the conductive film can be limited.

### Embodiment 3

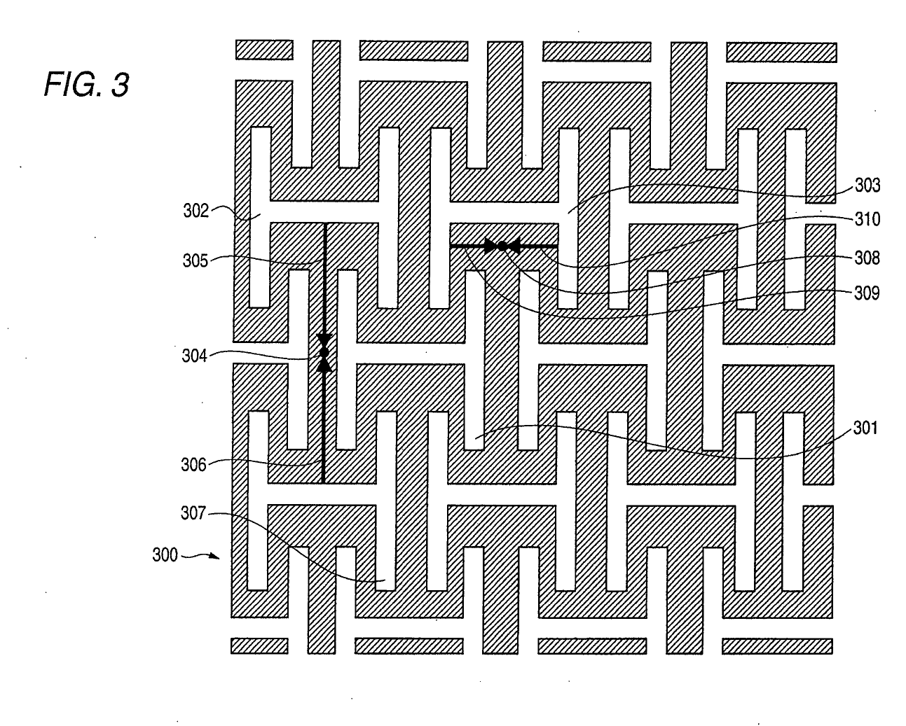

FIG. 3 is a plan view of a conductive film of the shield substrate when seen from above according to the third embodiment of this invention. In the following description, like reference symbols refer to like constituent elements in the above description, and the description thereof is omitted. The feature of this embodiment resides in that H-like slits are formed in an array on a conductive film.

In order to make these slits, first, a H-like slit 301 is formed on a conductive film 300. Next, two other H-like slits 302 and 303 are arranged to fall within a concave portion of the H-like slit 301. Next, all the H-like slits are arranged vertically and horizontally in an array to provide a configuration of the H-like slits 301, 302, 303.

In accordance with this configuration, for a thermal stress working point 304, a thermal stress accumulating line 305 is interrupted by the H-like slit 302 and a thermal stress accumulating line 306 is interrupted by the H-like slit 307. Further, for a thermal stress working point 308, a thermal stress accumulating line 309 is interrupted by the H-like slit 303 and a thermal stress accumulating line 310 is interrupted by the H-like slit 303. In this way, in all the directions of the points where thermal stress accumulates, the length of the straight line on the conductive film can be limited.

### Embodiment 4

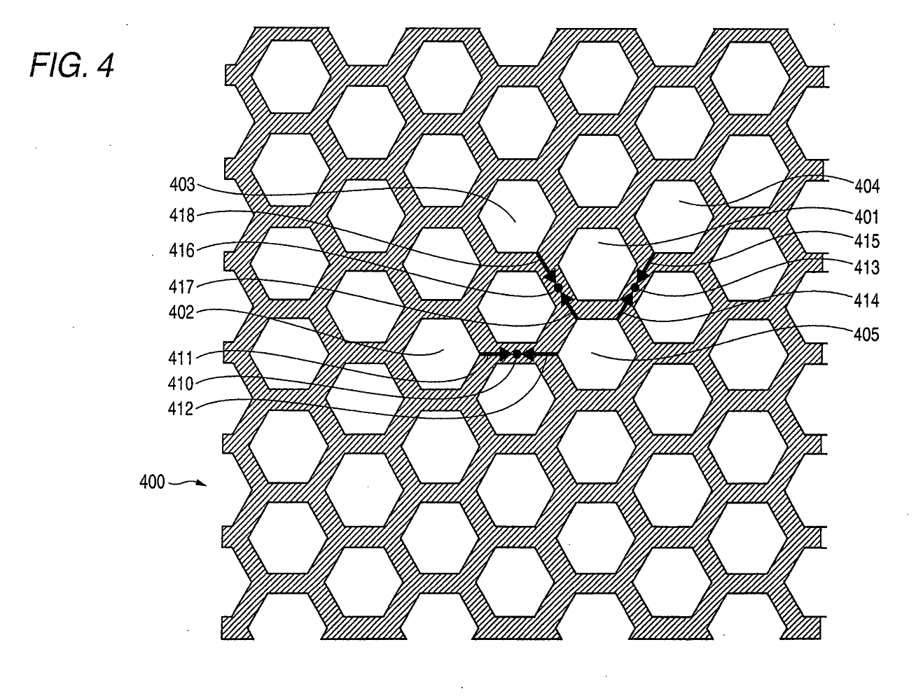

FIG. 4 is a plan view of a conductive film of the shield substrate when seen from above according to the fourth embodiment of this invention. In the following description, like reference symbols refer to like constituent elements in the above description, and the description thereof is omitted. The feature of this embodiment resides in that regular-hexagonal slits are formed on a conductive film, as shown in FIG. 4.

In order to make these slits, first, a regular-hexagonal slit 401 is formed on a conductive film 400. Next, the regular-hexagonal slits 401 are arranged in directions of oblique-60 degrees to provide regular-hexagonal slits 402, 403, 404, 405 in an array.

In accordance with this configuration, for a thermal stress working point 410, a thermal stress accumulating line 411 is interrupted by the regular-hexagonal slit 402 and a thermal stress accumulating line 412 is interrupted by the regular-hexagonal slit 405.

Further, for a thermal stress working point 413, a thermal stress accumulating line 414 is interrupted by the regular-hexagonal slit 405 and a thermal stress accumulating line 415 is interrupted by the regular-hexagonal slit 404. For a thermal stress working point 416, a thermal stress accumulating line 417 is interrupted by the regular-hexagonal slit 405 and a thermal stress accumulating line 418 is interrupted by the regular-hexagonal slit 403. In this way, in all the directions of the points where thermal stress accumulates, the length of the straight line on the conductive film can be limited.

Incidentally, in this embodiment, an example of the arrangement of only the regular-hexagonal slits has been explained. Without being limited to such an example, the shape of the slit may be any other polygon such as a triangle, or may be a combination of a plurality of polygons such as a combination of a pentagon and a hexagon.

### Embodiment 5

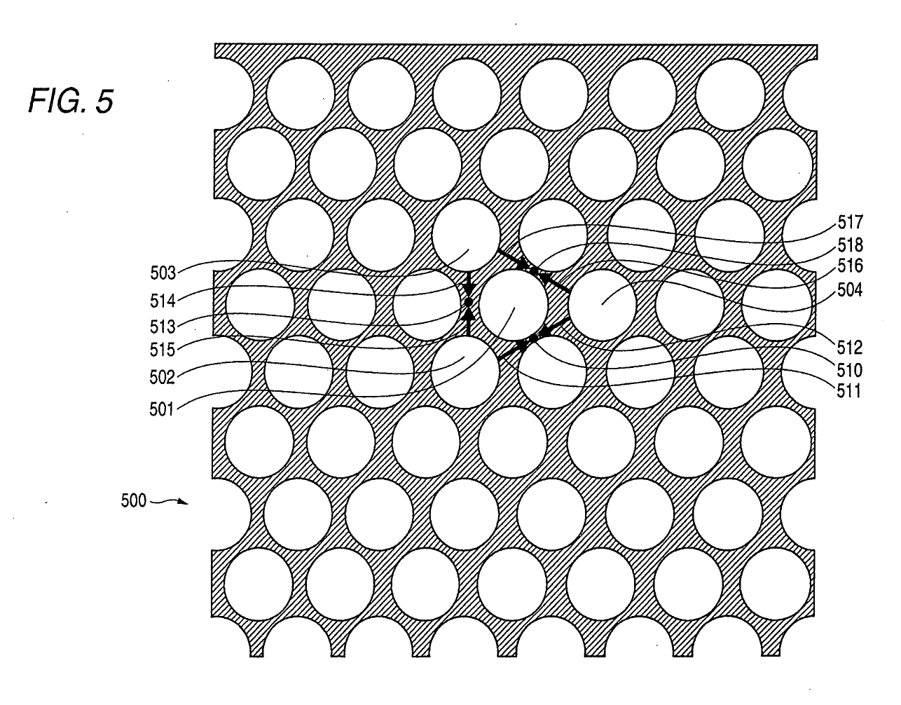

FIG. 5 is a plan view of a conductive film of the shield substrate when seen from above according to the fifth embodiment of this invention. In the following description, like reference symbols refer to like constituent elements in the above description, and the description thereof is omitted. The feature of this embodiment resides in that round slits are formed on a conductive film, as shown in FIG. 5.

In order to make these slits, first, a round slit 501 is formed on a conductive film 500. Next, the round slits 501 are arranged in directions of oblique-60 degrees to provide round slits 502, 503, 504 in an array.

In accordance with this configuration, for a thermal stress working point 510, a thermal stress accumulating line 511 is interrupted by the round slit 502 and a thermal stress accumulating line 512 is interrupted by the round slit 504. Further, for a thermal stress working point 513, a thermal stress accumulating line 514 is interrupted by the round slit 503 and a thermal stress accumulating line 515 is interrupted by the round slit 502.

For a thermal stress working point 516, a thermal stress accumulating line 517 is interrupted by the round slit 503 and a thermal stress accumulating line 518 is interrupted by the round slit 504. In this way, in all the directions of the points where thermal stress accumulates, the length of the straight line on the conductive film can be limited.

### Embodiment 6

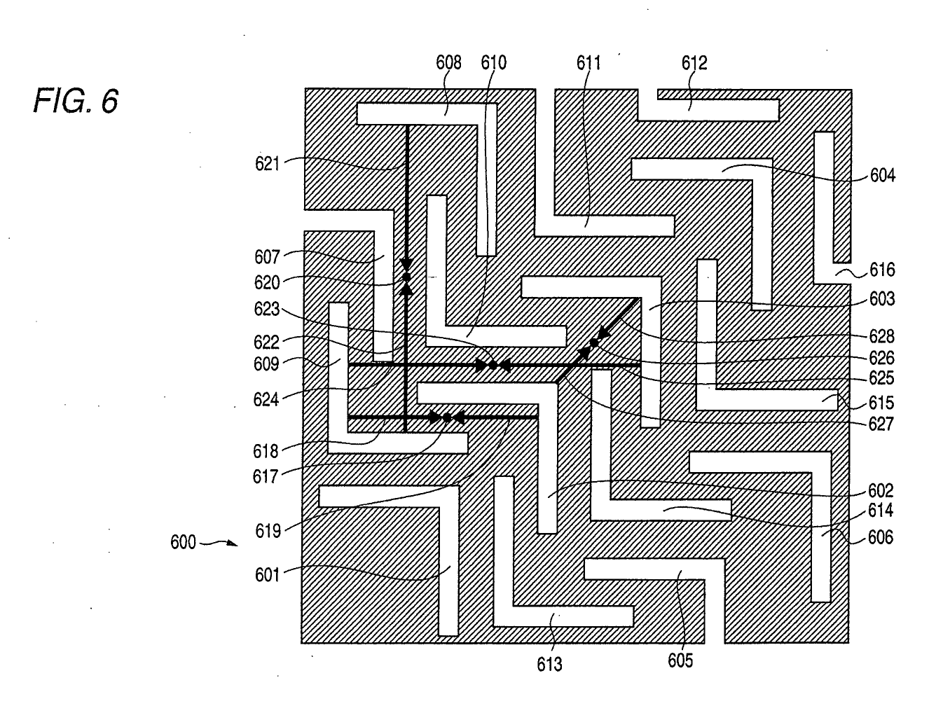

FIG. 6 is a plan view of a conductive film of the shield substrate when seen from above according to the sixth embodiment of this invention. In the following description, like reference symbols refer to like constituent elements in the above description, and the description thereof is omitted. The feature of this embodiment resides in that L-like slits are formed on a conductive film.

In order to make these slits, first, an L-like slit 601 is formed on a conductive film 600. Next, the L-like slits 601 are arranged in directions of oblique-45 degrees to provide L-like slits 602, 603, 604, 605, 606, 607, 608 in an array.

Next, L-like slits 609 which are made by rotating the above L-like slits by 180 degrees are arranged in directions of 45 degrees to provide above-described L-like slits 610, 611, 612, 613, 614, 615, 616 in an array, so as to sandwich the L-like slits 601, 602, 603, 604, 605, 606, 607, 608.

In accordance with this configuration, for a thermal stress working point 617, a thermal stress accumulating line 618 is interrupted by the L-like slit 609 and a thermal stress accumulating line 619 is interrupted by the L-like slit 602. Further, for a thermal stress working point 620, a thermal stress accumulating line 621 is interrupted by the L-like slit 608 and a thermal stress accumulating line 622 is interrupted by the L-like slit 609.

For a thermal stress working point 623, a thermal stress accumulating line 624 is interrupted by the L-like slit 609 and a thermal stress accumulating line 625 is interrupted by the L-like slit 603. For a thermal stress working point 626, a thermal stress accumulating line 627 is interrupted by the L-like slit 602 and a thermal stress accumulating line 628 is interrupted by the L-like slit 603.

In this way, in all the directions of the points where thermal stress accumulates, the length of the straight line on the conductive film 600 can be limited.

### Embodiment 7

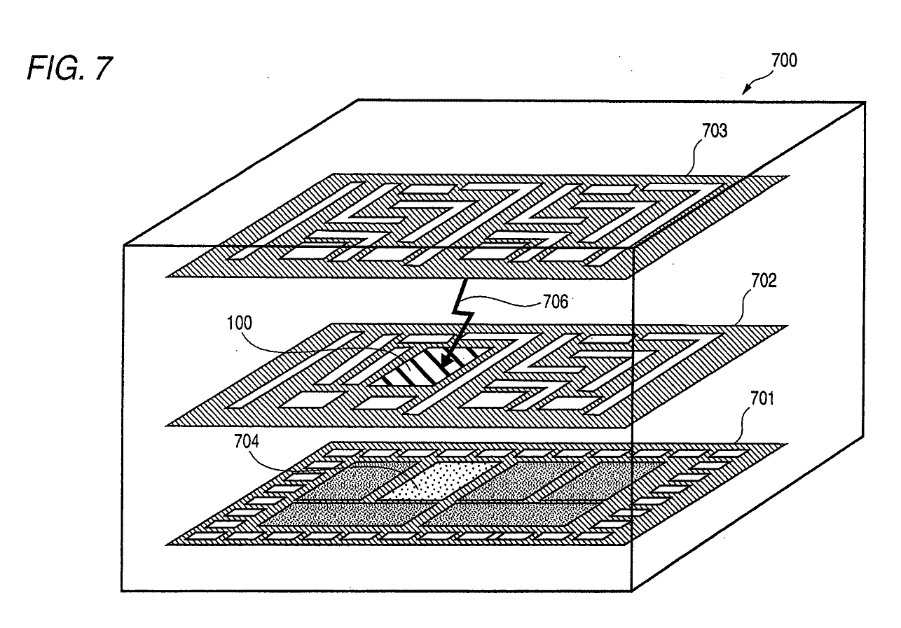

FIG. 7 is a schematic arrangement view of a semiconductor package according to the seventh embodiment of this invention. As seen from FIG. 7, a semiconductor package 700 consists of a semiconductor chip 701, a first wiring board 702 and a second wiring board 703.

On the semiconductor chip 701, a plurality of circuits are formed. Among them, a circuit 704 is a circuit which is an object for noise protection. Further, in order to interrupt the radiating noise 706 generated from the second wiring board 703, the conductive film 100 shown in FIG. 1 B as the shield film is formed on the first wiring board 702.

The first wiring board 702 having the conductive film 100 is formed between the semiconductor chip 701 and the second wiring board 703. The conductive film 100 on the first wiring board 702 is formed to overlie the noise protection objective circuit 704 on the semiconductor chip 701.

In this way, the semiconductor package 700 has the conductive film 100 on the first wiring board 702 at an area overlapping the position to which the noise protection objective circuit 704 on the semiconductor chip 701 is extended vertically. For this reason, the radiating noise 706 generated from the second wiring board 703 does not propagate to the noise protection objective circuit 704 on the semiconductor chip.

Further, the conductive film 100, as described above, is formed so that the thermal stress propagated from the semiconductor chip is interrupted by the slits and so is not excessively concentrated, thereby preventing crack or flake-off from occurring on the conductive film 100. Thus, it is possible to prevent the leakage of the radiating noise 706 due to the crack of the conductive film 100 from giving rise to the failure such as causing the protection objective circuit 704 of the semiconductor chip to malfunction, thereby realizing the semiconductor package 700 with improved reliability.

Incidentally, the shape of the slits on the conductive film is not limited to the shape shown in FIG. 1 B but may be the rectangular, H-like, regular-hexagonal, round or L-like shape as shown in FIGS. 2 to 6.

### Embodiment 8

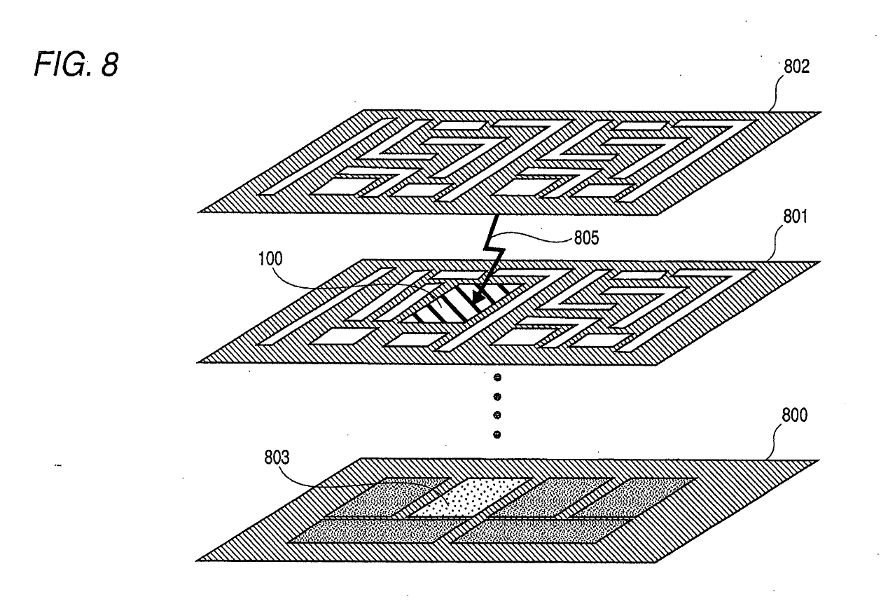

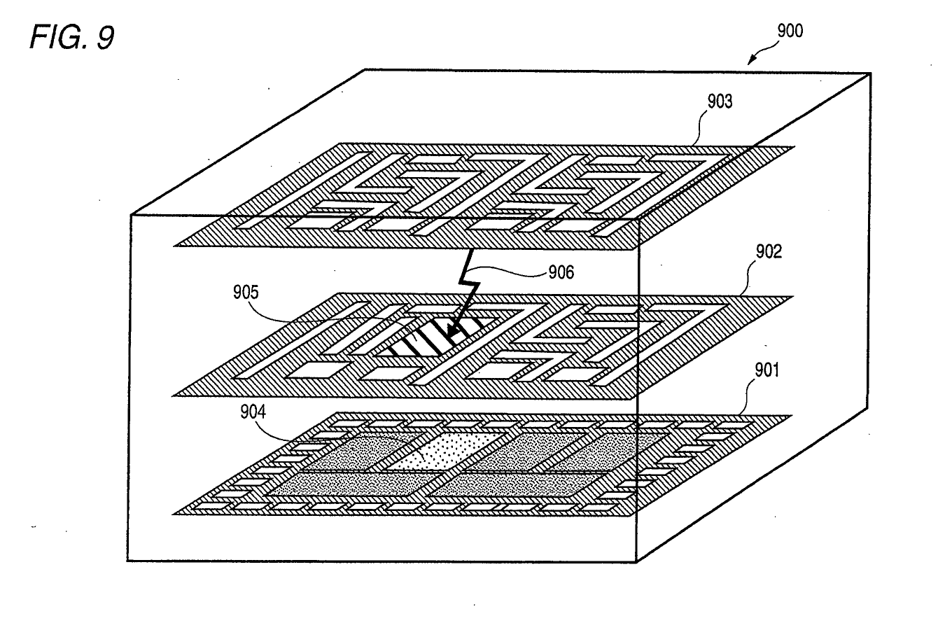

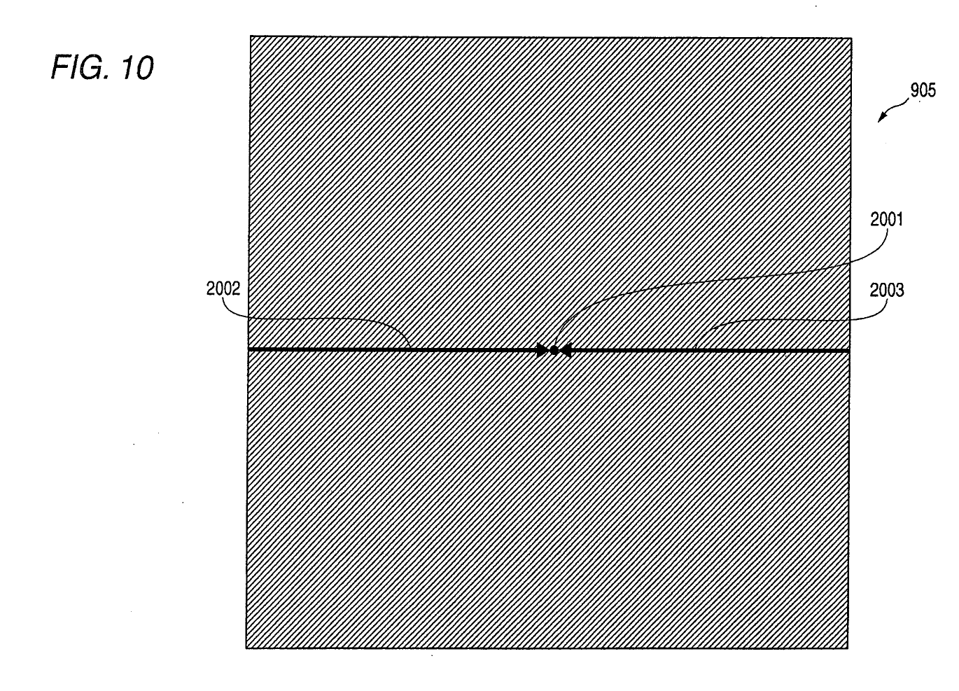

FIG. 8 is a schematic arrangement view of a semiconductor device according to the eighth embodiment of this invention. As seen from FIG. 8, the semiconductor device includes a silicon substrate 800, a first wiring layer 801 and a second wiring layer 802.

On the silicon substrate 800, a plurality of circuits are formed. Among them, a circuit 804 is a circuit which is an object for noise protection. Further, in order to interrupt the radiating noise 805 generated from the second wiring board 802, the conductive film 100 shown in FIG. 1 B as the shield film is formed on the first wiring board 801.

The first wiring board 801 having the conductive film 100 is formed between the silicon substrate 800 and the second wiring layer 802. The conductive film 100 on the first wiring board 801 is formed to overlie the noise protection objective circuit 804 on the silicon substrate 800.

In this way, the semiconductor device according to this embodiment has the conductive film 100 on the first wiring layer 801 in an area overlapping the position to which the noise protection objective circuit 804 on the silicon substrate 800 is extended vertically. For this reason, the radiating noise 805 generated from the second wiring layer 802 does not propagate to the noise protection objective circuit 804 on the semiconductor substrate.

Further, the conductive film 100, as described above, is formed so that the thermal stress propagated from the circuit on the silicon substrate is interrupted by the slits and so is not excessively concentrated, thereby preventing crack or flake-off from occurring on the conductive film 100. Thus, it is possible to prevent the leakage of the radiating noise 805 due to the crack of the conductive film 100 from giving rise to the failure such as causing the protection objective circuit 804 of the silicon substrate to malfunction, thereby realizing the semiconductor device with improved reliability.

Incidentally, the shape of the slits on the conductive film is not limited to the shape shown in FIG. 1B but may be the rectangular, H-like, regular-hexagonal, round or L-like shape as shown in FIGS. 2 to 6.

This invention is useful for improving resistance of the shield substrate, semiconductor package and semiconductor device to thermal stress thereby to improve their reliability.

What is claimed is:

1. A shield substrate provided with a conductive film on which slits each having a shape through which electromagnetic wave noise does not leak are formed.

2. The shield substrate according to claim 1, wherein said slits are rectangular slits and formed in an array on said conductive film.

3. The shield substrate according to claim 1, wherein said slits are H-like slits and formed in an array on said conductive film.

4. The shield substrate according to claim 1, wherein said slits are polygonal slits and formed in an array on said conductive film.

5. The shield substrate according to claim 1, wherein said slits are round slits and formed in an array on said conductive film.

6. The shield substrate according to claim 1, wherein said slits are L-like slits and formed in an array on said conductive film.

7. A semiconductor package comprising:
a first wiring board which is a source generating electromagnetic wave noise;
a semiconductor chip having a noise protection objective circuit; and
a second wiring board arranged between said first wiring board and said semiconductor chip and having a conductive film capable of shielding said electromagnetic wave noise, wherein slits each having a shape through which electromagnetic wave noise does not leak are formed on said conductive film.

8. The semiconductor package according to claim 7, wherein said slits are rectangular slits and formed in an array on said conductive film.

9. The semiconductor package according to claim 7, wherein said slits are H-like slits and formed in an array on said conductive film.

10. The semiconductor package according to claim 7, wherein said slits are polygonal slits and formed in an array on said conductive film.

11. The semiconductor package according to claim 7, wherein said slits are round slits and formed in an array on said conductive film.

12. The semiconductor package according to claim 7, wherein said slits are L-like slits and formed in an array on said conductive film.

13. A semiconductor device comprising:
a first wiring layer which is a source generating electromagnetic wave noise;
a silicon substrate having a noise protection objective circuit; and
a second wiring layer arranged between said first wiring layer and said silicon substrate and having a conductive film capable of shielding said electromagnetic wave noise from said noise protection objective circuit,
wherein slits each having a shape through which electromagnetic wave noise does not leak are formed on said conductive film.

14. The semiconductor device according to claim 13, wherein said slits are rectangular slits and formed in an array on said conductive film.

15. The semiconductor device according to claim 13, wherein said slits are H-like slits and formed in an array on said conductive film.

16. The semiconductor device according to claim 13, wherein said slits are polygonal slits and formed in an array on said conductive film.

17. The semiconductor device according to claim 13, wherein said slits are round slits and formed in an array on said conductive film.

18. The semiconductor device according to claim 13, wherein said slits are L-like slits and formed in an array on said conductive film.
